(19) United States
(12) Patent Application Publication
(10) Pub. No.: US 2023/0025354 A1
(43) Pub. Date: Jan. 26, 2023

(54) Method And Apparatus For Singulation Detachment

(71) Applicant: Hutchinson Technology Incorporated, Hutchinson, MN (US)

(72) Inventors: Erich W. Bierbrauer, Hutchinson, MN (US); Nole D. German, Hutchinson, MN (US)

(21) Appl. No.: 17/869,684

(22) Filed: Jul. 20, 2022

Related U.S. Application Data
(60) Provisional application No. 63/223,892, filed on Jul. 20, 2021.

(51) Int. Cl. H05K 3/32; H05K 13/00; H05K 3/00

(52) U.S. Cl. CPC H05K 3/326; H05K 13/0069; H05K 3/007; H05K 2203/0152

(57) ABSTRACT

A component is disclosed. A component includes an elongated body, with a first end and a second end; and one or more tabs at the first end and the second end, the tabs configured to have a lower tensile strength than other regions of the component.

### CROSS-REFERENCE TO RELATED APPLICATIONS

This application claims the benefit of, and priority to, U. S. Provisional Application No. 63/223,892 filed on Jul. 20, 2021, which is hereby incorporated by reference in its entirety.

### FIELD

Examples of the present disclosure relate to the field of manufacturing components. More particularly, examples of the present disclosure relate to a method and apparatus for separating such components from a locating and transport structure.

### BACKGROUND

In many applications, a plurality of components (e.g., electronic micro-components) are formed simultaneously in a panel using a plurality of forming processes (e.g., etching, plating, etc.) To secure the components within the panel during the forming processes, each of the plurality of components are coupled to a carrier strip of the panel using one or more removable tabs. Often, removal of these removable tabs requires etching, cutting, or fracturing of the removable tabs.

### SUMMARY

A metal component is disclosed. A metal component includes an elongated body, with a first end and a second end; and one or more tabs at the first end and the second end, the tabs configured to have a lower tensile strength than other regions of the metal component.

In another aspect, a panel is disclosed. The panel generally comprises at least one component including at least one tab coupled with a rigid breaking point, the at least one tab including at least one component. The at least one component includes an elongated body, with a first end and a second end, and the at least one tab between the panel and the first end, the tabs having a lower tensile strength than other regions of the at least one component.

In another aspect a method for detaching a component from a panel, wherein the panel including a locating and transport structure integrally connected to the component by a tab, is provided. In some embodiments the method generally comprises the steps of: holding the component in a first fixed location; holding the locating and transport structure in a second fixed location; and enabling a pressure pad with a vacuum to lift the component at the tabs along a direction generally perpendicular away from the locating and transport structure, the vacuum lift generates a tensile load sufficient to fracture the tab.

While multiple examples are disclosed, still other examples of the present disclosure will become apparent to those skilled in the art from the following detailed description, which shows and describes illustrative examples of this disclosure. Accordingly, the drawings and detailed description are to be regarded as illustrative in nature and not restrictive.

### BRIEF DESCRIPTION OF THE DRAWINGS

FIG. 1 is a top plan view of a component including a detachment region, in accordance with an example of the disclosure.

FIG. 2 is a bottom plan view of a component including a detachment region, in accordance with an example of the disclosure.

FIG. 3 illustrates an attachment interface between the metal component and the detachment region of a panel in accordance with an example of the disclosure.

FIG. 4 illustrates an alternative attachment interface between the detachment region and the breaking region of the component, in accordance with an example of the disclosure.

FIG. 5 illustrates the separation of the detachment region from the detachment point and a tab, in accordance with an example of the disclosure.

FIG. 6 is a side perspective view of the detachment region after separating from the tab, in accordance with an example of the disclosure.

FIG. 7 is a side perspective view of the detachment region after separating from the tab incorporating a support region, in accordance with an example of the disclosure.

FIGS. 8A-8B illustrate exemplary semi-finished suspension products manufactured using a carrier strip or panel in accordance with an example of the disclosure.

FIGS. 9A-9B illustrate a perspective view of an apparatus for detaching the components from a panel, in accordance with an example.

FIGS. 10A-10B illustrate the apparatus in the process of detaching the components from the locating and transport structure, in accordance with an example.

FIGS. 11A-11B illustrate a perspective view of an alternative apparatus for detaching the components from the locating and transport structure, in accordance with an example.

### DETAILED DESCRIPTION

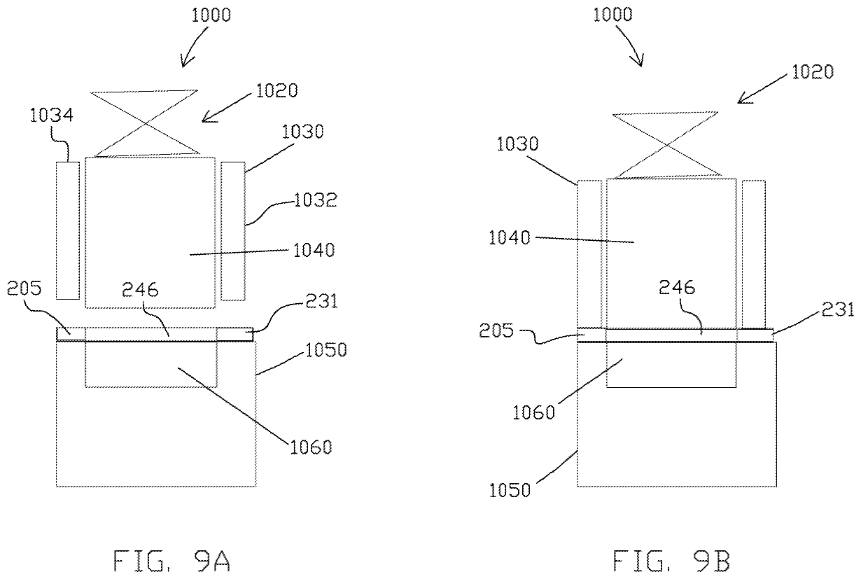

Further, the number and design of these removable tabs can increase the number of components that can be formed in a given panel. As will be detailed herein, tensile loads are applied to the metal component by an apparatus (e.g. a spring pressure pad) to cause tabs of the metal component to fracture, effectively detaching the one or more tabs from the panel. The details of an example apparatus will be discussed below with respect to FIGS. 9A-11B.

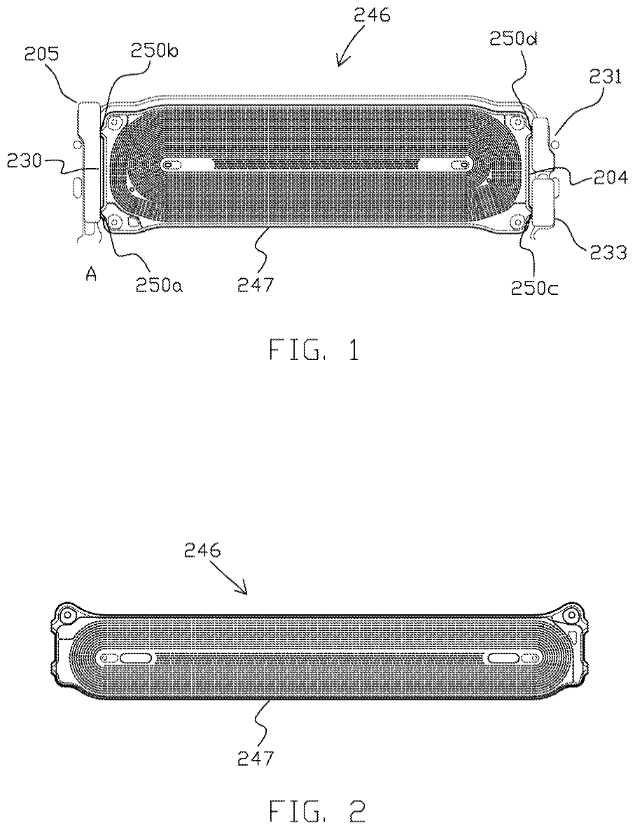

FIG. 1 illustrates a top plan view of a metal component 246, in accordance with an example of the disclosure. The metal component 246 can include the metal component of a semi-finished product. In some examples, the metal component 246 is configured as a coil component. The metal component 246 includes an elongated body 247 with a first end 204 and a second end 230, and tabs 250a-d. The tabs 250a-d are formed between a panel and the metal component 246. The tabs 250a-d includes a reduced cross-sectional area, which results in higher stress at the tabs 250a-d as compared to the rest of the metal component 246. This higher stress and the lower load bearing capability of the tabs 250a-d causes the tabs 250a-d to fracture rather than the rest of the metal component 246.

The first end 204 of the metal component 246 is connected to a first detachment area of the panel through one or more tabs 250a-d. The second end 230 of the metal component 246 is integrally connected to a second detachment area of a panel via a second detachment area. The detachment areas include one or more a rigid breaking points 205. The top surface of the metal component 246 is made from stainless-steel, for some embodiments. FIG. 2 is a bottom plan view of the metal component 246, specifically illustrating a bottom surface, in accordance with an example of the disclosure. The bottom surface of the metal component 246 includes one or more circuit components. For some embodiments, the metal component 246 includes a copper layer arranged as a coil.

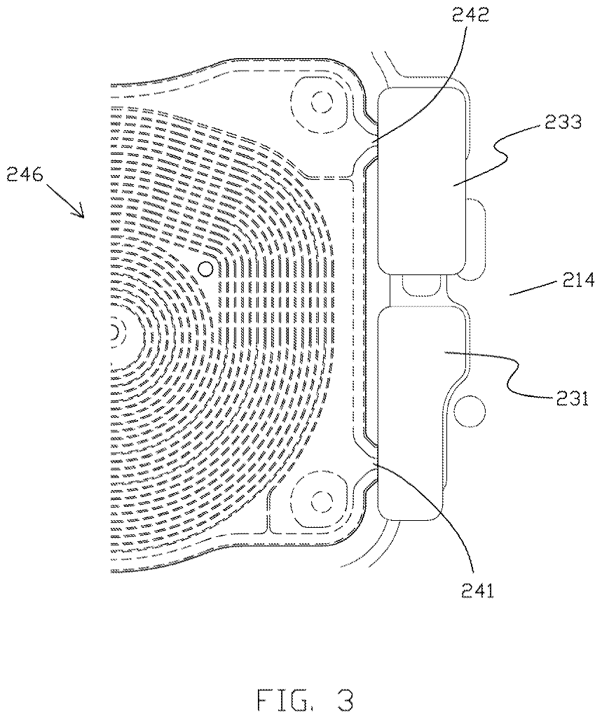

FIG. 3 illustrates an attachment interface between the metal component 246 and the detachment area of a panel in accordance with an example of the disclosure. The metal component 246 includes detachment tabs 242 and 241. The detachment area 214 includes rigid breaking points 233 and 231. The detachment tab 242 is integrally connected to the rigid breaking point 233 at an interface. In some examples, the detachment tab 242 has the thinnest cross-sectional area at the interface. The rigid breaking points 233 and 231 are formed from stainless-steel, according to some embodiments, as a rigid base to enable the detachment tabs 242 and 241 to break at a desired location. The rigid breaking point 233, according to some embodiments, is formed from stainless steel and are configured as a top shear bar.

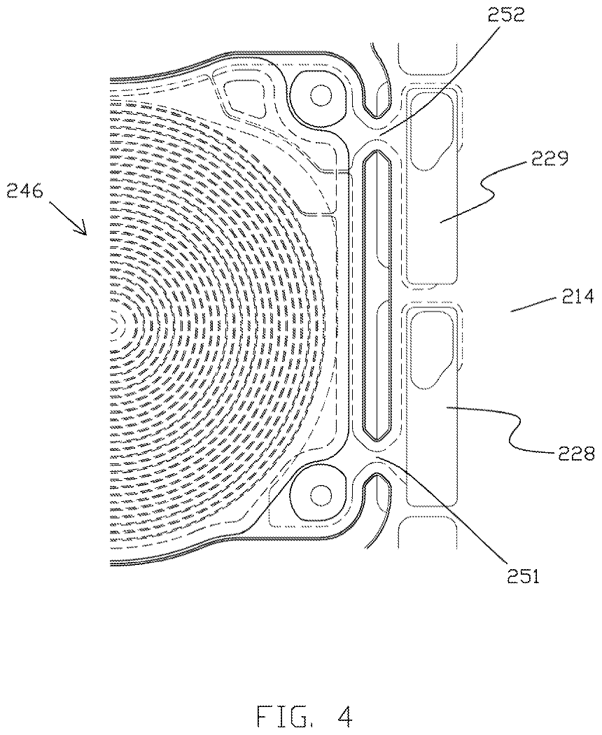

FIG. 4 illustrates an alternative attachment interface between the metal component 246 and the detachment area 214 of the panel, in accordance with an example of the disclosure. For the purposes of this illustration, the alternative attachment interface can be the underside of the attachment interface of FIG. 4. The metal component 246 can include breaking interfaces 252 and 251. The detachment area 214 includes detachment points 229 and 228. The breaking interfaces 252 and 251 are integrally connected to the detachment points 229 and 228 of the panel. Each of the breaking interfaces 252 and 251 can be configured as a stress riser, which is configured to detach from a metal break of the detachment points 229 and 228. In some examples, the detachment points 229 and 228 can be made up of copper to provide a rigid base to enable the breaking interfaces 252 and 251 to break at a desired location.

FIG. 5 illustrates the separation of the metal component 246 from the rigid breaking points 231 and 205, in accordance with an example of the disclosure. A single force, or a combination of forces may act on the metal component 246, which propels the metal component 246 in direction 40. The forces may include, for example, a vacuum force on a top surface of the metal component, and a normal force acting on the bottom surface of the detachment region acting in direction 40. The direction 40 is generally perpendicular away from the locating and transport structure. The single force or combination of forces may cause the separation of a head suspension component from a semi-finished suspension product.

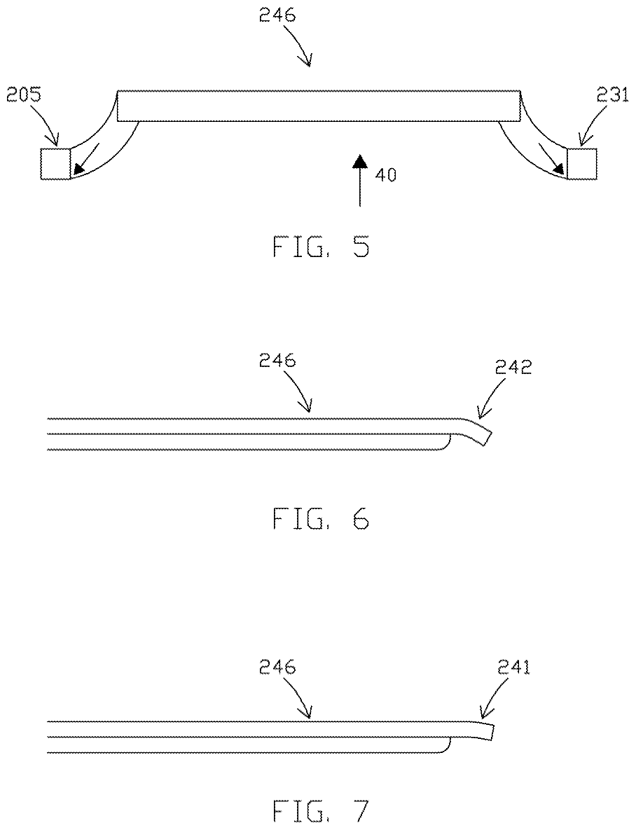

FIG. 6 is a side perspective view of the metal component 246 after separating from the tab, in accordance with an example of the disclosure. The metal component 246 is lifted while the tab and panel are fixed in place. In this example, the normal force acting on the bottom surface of the detachment region is not applied. The detachment region was separated from the tab using a vacuum force on the top surface. As a result, the detachment tab 242 is bent downward from the applied force.

FIG. 7 is a side perspective view of the detachment region after separating from the tab using the normal force acting on the bottom surface of the metal component 246, in accordance with an example of the disclosure. As a result, the detachment tab 241 is bent less than the detachment tab 242 example of FIG. 6.

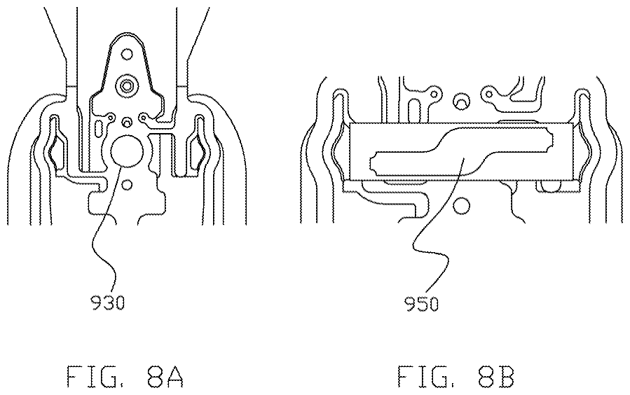

FIGS. 8A-8B illustrate exemplary semi-finished components manufactured using a carrier strip or panel disclosed herein. For example, FIG. 8A illustrates a microactuator motor pad 930 that can be manufactured using the carrier strip of the present disclosure. FIG. 8B illustrates a microactuator stiffener 950 that can be manufactured using the carrier strip or panel.

FIGS. 9A-9B illustrate a perspective view of an apparatus 1000 for detaching at least one metal component from a panel, in accordance with an example of the disclosure. The apparatus 1000 includes a spring member 1020, a vacuum head 1030, and an ejector 1050. The component is positioned between the vacuum head 1030 and the ejector 1050. The vacuum head 1030 includes a vacuum pad 1040 coupled to the spring member 1020. The vacuum head also includes a first clamp device 1032 and a second clamp device 1034 on opposing sides of the vacuum pad 1040. The vacuum pad 1040 is biased towards the ejector 1050. The ejector 1050 includes an ejector pin tool 1060 configured with the cross-dimensions of the metal component 246.

The panel is advanced through the apparatus 1000 in a stepwise manner using techniques including those known in the art. As a result, the apparatus 1000 will act on each detachment region of a panel as it advances through the apparatus 1000.

FIG. 9A illustrates the apparatus 1000 in a pre-pick position. The metal component 246 is positioned on a support surface of the ejector pin tool 1060. Whereas, the rigid breaking point 231 of the detachment area of the panel is positioned on a first support surface of the ejector 1050. The rigid breaking point 231 is positioned just beneath the first clamp device 1032. Similarly, the rigid breaking point 205 of the tab is positioned on a second support surface of the ejector 1050. The first and second support surfaces are positioned on opposite sides of the support surface of the ejector pin tool 1060. The rigid breaking point 205 is positioned just beneath the second clamp device 1034.

FIG. 9B illustrates the apparatus 1000 in a picked position. The vacuum pad 1040, the first and second clamp devices 1032 and 1034 are respectively driven by the spring member 1020. It should be understood that the vacuum head 1030 can incorporate multiple spring members, for example, one spring member for each element. The first and second clamp devices 1032 and 1034 respectively clamp the rigid breaking point 205 of the tab and the rigid breaking point 231 of the detachment area of the panel. The clamping process will be discussed in detail below. The vacuum pad 1040 can make contact with the metal component 246. In some examples, the ejector pin tool 1060 is retracted using the spring member 1020, lifting the metal component 246.

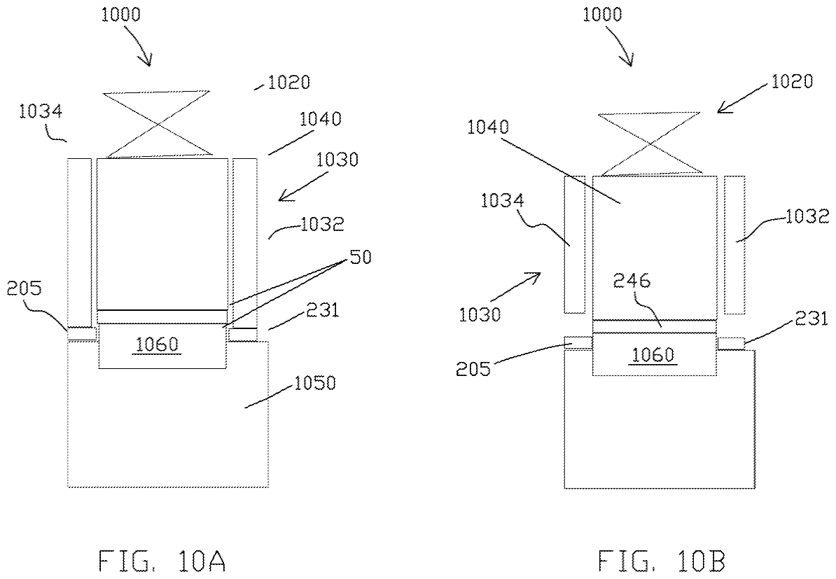

FIGS. 10A-10B illustrate the apparatus in the process of detaching the metal component 246 from the locating and transport structure, in accordance with an example of the disclosure. Specifically, FIG. 10A illustrates the ejector pin tool 1060 retracted using the spring member 1020, lifting the metal component 246. FIG. 10A illustrates a tolerance 50 so the removal of the metal component 246 is a fracture and not a shear. FIG. 10B illustrates the first and second clamp devices 1032 and 1034 retracted using the spring member 1020, releasing the rigid breaking point 205 of the tab and the rigid breaking point 231 of the detachment area of the panel. The metal component 246 is removed from the rigid breaking point 205 of the tab and the rigid breaking point 231 of the detachment area of the panel.

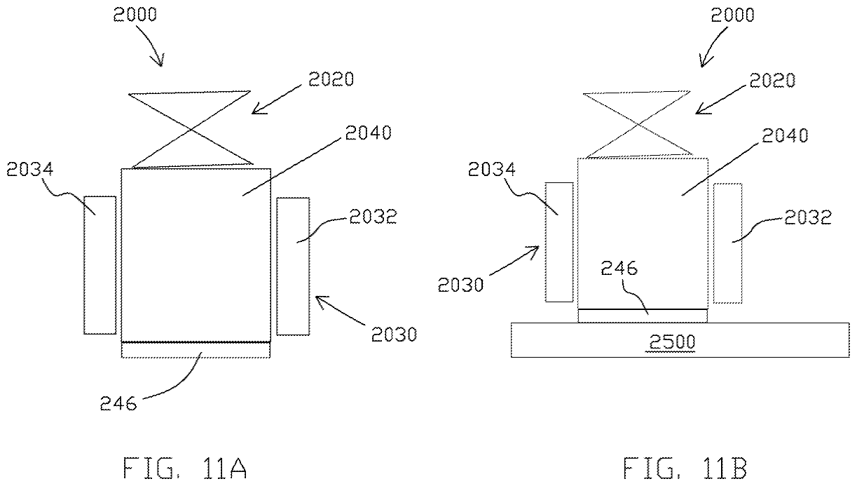

FIGS. 11A-11B illustrate a perspective view of an exemplary alternative apparatus 2000 for detaching the metal component 246 from the locating and transport structure. The apparatus 2000 includes a spring member 2020, a vacuum head 2030, and a substrate 2500. The semi-finished suspension product is positioned between the vacuum head 2030 and the substrate 2500. The vacuum head 2030 includes a vacuum pad 2040 coupled to the spring member 2020. The vacuum head 2030 also includes a first clamp device 2032 and a second clamp device 2034 on opposing sides of the vacuum pad 2040. The vacuum pad 2040 is biased towards the substrate 2500. The metal component 246 can be received on the substrate 2500 configured to receive the metal component 246.

The panel is advanced on the substrate 2500, using techniques including those known in the art. As a result, the apparatus 2000 will pick one or more metal components 246 from one or more panels and advances to place the one or more components on the substrate 2500.

FIG. 11A illustrates the apparatus 2000 in a pre-place position. FIG. 11B illustrates the apparatus 2000 in a place position. The vacuum pad 2040, the first and second clamp devices 2032 and 2034 are respectively driven by the spring member 2020. It should be understood that the vacuum head 2030 can incorporate multiple spring members, for example, one spring member for each element. The first and second clamp devices 2032 and 2034 respectively clamp the rigid breaking point of the tab and the rigid breaking point of the detachment area of the panel. The vacuum pad 2040 can be operable to contact the metal component 246. In some examples, the vacuum pad 2040 is retracted using the spring member 2020, placing the metal component 246 on the substrate 2500.

While multiple examples are disclosed, still other examples within the scope of the present disclosure will become apparent to those skilled in the art from the detailed description provided herein, which shows and describes illustrative examples. Accordingly, the drawings and detailed description are to be regarded as illustrative in nature and not restrictive. Features and modifications of the various examples are discussed herein and shown in the drawings. While multiple examples are disclosed, still other examples of the present disclosure will become apparent to those skilled in the art from the following detailed description, which shows and describes illustrative examples of this disclosure. Accordingly, the drawings and detailed description are to be regarded as illustrative in nature and not restrictive.

What is claimed is:

1. A component comprising:
an elongated body, with a first end and a second end; and
one or more tabs at the first end and the second end, the tabs configured to have a lower tensile strength than other regions of the component.

2. The component of claim 1, comprising a top side and an opposing bottom side, the top side is made up of stainless steel.

3. The component of claim 1, comprising a top side and an opposing bottom side, the opposing bottom side includes a metal layer arranged as a coil.

4. The component of claim 1, wherein the one or more tabs are coupled with one or more rigid breaking points.

5. The component of claim 4, wherein the rigid breaking point of the component is made up of stainless-steel.

6. The component of claim 5, wherein the rigid breaking point is configured as a top shear bar.

7. The component of claim 5, wherein the rigid breaking point is formed on a panel.

8. A panel comprising:
at least one component including at least one tab coupled with a rigid breaking point, the at least one tab including at least one component, the at least one component including:
an elongated body, with a first end and a second end, and
the at least one tab between the panel and the first end, the tabs having a lower tensile strength than other regions of the at least one component.

9. The panel of claim 8, wherein a second tab is positioned between the second end and the panel.

10. The panel of claim 8, wherein the component includes a top side and an opposing bottom side, the top side is formed from stainless steel.

11. The panel of claim 8, wherein the component includes a top side and an opposing bottom side, the bottom side includes a metal layer arranged as a coil.

12. The panel of claim 8, wherein the rigid breaking point of the component is formed from copper.

13. The panel of claim 8, wherein the rigid breaking point of the component includes stainless-steel.

14. The panel of claim 13, wherein the rigid breaking point of the detachment point is configured as a top shear bar.

15. The panel of claim 13, wherein the rigid breaking point is configured as a fracture tab.

16. A method for detaching a component from a panel, the panel including a locating and transport structure integrally connected to the component by a tab, the method comprising:
holding the component in a first fixed location;
holding the locating and transport structure in a second fixed location; and
enabling a pressure pad with a vacuum to lift the component at the tabs along a direction generally perpendicular away from the locating and transport structure, the vacuum lift generates a tensile load sufficient to fracture the tab.

17. The method of claim 16, wherein the pressure pad includes stress risers configured to detach the component.

18. The method of claim 16, wherein the component includes a top side and an opposing bottom side, the top side includes stainless steel.

19. The method of claim 16, wherein the metal component includes a top side and an opposing bottom side, the bottom side includes a metal layer arranged as a coil.

20. The method of claim 16, wherein the locating and transport structure includes at least a second component.
